(19) United States
(12) Patent Application Publication
(10) Pub. No.: US 2009/0298698 A1
(43) Pub. Date: Dec. 3, 2009

(54) HIGH-TEMPERATURE SUPERCONDUCTOR LAYER ARRANGEMENT

(75) Inventors: Michael BACKER, Koln (DE); Oliver BRUNKAHL, Remagen (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: ZENERGY POWER GMBH, Rheinbach (DE)

(21) Appl. No.: 12/412,530

(22) Filed: Mar. 27, 2009

(30) Foreign Application Priority Data
Mar. 29, 2008 (DE) 10 2008 016 257.4

(51) Int. Cl. H01L 39/12; B32B 3/00; H01L 39/24

(52) U.S. Cl. 505/239; 505/470; 427/62; 428/141

(57) ABSTRACT

A high-temperature superconductor layer arrangement includes at least one substrate and a textured buffer layer made of oxidic material that permits textured growth of a high-temperature superconductor. Surprisingly, a layer of the buffer material made of a rare-earth element cerium oxide containing lanthanum as the rare-earth element may be used to produce a homogeneous buffer layer in just one coating operation, where appropriate. The buffer layer material may be a rare-earth oxide of the general formula: Ln′₂₋ₓLn″ₓCe′_{2-y}M″_{y}O_{7±z}, wherein 0≦x, y, z≦1, in which Ln′ and Ln″ each represents a rare-earth element, independently of each other, and M″ represents a trivalent or tetravalent or pentavalent metal.

### BACKGROUND OF THE INVENTION

This invention relates to a high-temperature superconductor (HTSC) layer arrangement comprising at least one substrate and a textured buffer layer that permits textured growth of an HTSC layer.

The buffer layer has a host of different functions. First, it should transfer texture as completely and perfectly as possible from the textured substrate, which displays the highest possible degree of texturing, to the HTSC layer to be grown. The substrate is biaxially textured to the greatest possible extent, i.e., both perpendicular to the layer and also in an axial direction within the layer. Corresponding biaxial texturing of the high-temperature superconductor is necessary to achieve high critical currents and high current densities. The buffer layer should also effectively prevent any diffusion of components or contaminants from the substrate into the HTSC layer, since this diffusion may reduce the critical current density and/or the absolute critical current of the high-temperature superconductor, or the superconductive state may be disrupted. Moreover, the buffer layer should display the greatest possible adhesive strength with respect to both the substrate and the high-temperature superconductor to be grown. The buffer layer must additionally display sufficient mechanical and temperature cycling properties under both manufacturing and operating conditions. Furthermore, the buffer layer should be such that it may be simply and reproducibly manufactured at a high process speed.

Moreover, the buffer layer material should display good growth properties on the substrate, which may comprise a metal or a metal alloy. Growth properties are, among other reasons, important for the quality of texture transfer, for the adhesive strength of the growing layer on the substrate, and also for the homogeneity of the growing layer. The growing layer should be as free as possible from microcracks, pores or other structural defects, and should be free from foreign phases, such as amorphous phases resulting from imperfect crystallization, precipitation phases, products of chemical side reactions, and the like. Furthermore, the buffer layer is, for its part, of decisive importance for the growth properties of the HTSC layer, for which the above-mentioned problems must again be taken into consideration.

Until now, a number of different materials were used as the buffer layer material, such as yttrium-stabilized zirconium oxide (YSZ), various zirconates, such as gadolinium zirconate, lanthanum zirconate and the like, titanates, such as strontium titanate, and simple oxides, such as cerium oxide, magnesium oxide and the like. To fulfill the complex and demanding requirements existing today, and particularly for guaranteeing a high degree of texture transfer and an efficient diffusion barrier, the buffer layer typically consists of layer combinations comprising multiple, different buffer materials. In some cases, five or more layers may be included.

It has been found, for example, that cerium oxide (CeO₂) is very suitable as a substrate for the HTSC layer to be grown. However, cerium oxide only forms a poor diffusion barrier, and is thus hardly suitable for growth directly on a metallic substrate. It has also been found that to achieve sufficient and rapid crystallization of cerium oxide, an excessively reducing atmosphere, such as forming gas (e.g., with approx. 2-5% by vol. H₂), is not suitable in the crystallization step. However, use of an atmosphere consisting of pure nitrogen has proven to be unsuitable for metallic substrates, owing to the traces of residual oxygen always present in the gas in the ppm range. These traces lead to oxidation, e.g., to formation of highly stable and undesirable nickel tungsten oxides in the case of tungsten-doped nickel strips. Therefore, modern HTSC layer arrangements are generally manufactured using buffer layers having a plurality of different individual layers made of different materials.

The application of several layers of buffer material is, however, extremely complex in terms of process engineering. It significantly reduces the production speed of the overall process for manufacturing a functional HTSC layer arrangement because it is necessary to perform an annealing step after applying each layer of buffer material before a further layer may be applied by chemical solution deposition (CSD). Thus, the cost of manufacturing the HTSC layer arrangement is largely determined by the processes for the formation of the buffer layer. However, use of a single-layer buffer layer made of conventional materials is unable to meet the complex requirements for a buffer.

There is moreover a need to further enhance the quality of high-temperature superconductor layers in terms of their homogeneity and texture. On the other hand, it goes without saying that the application of numerous buffer layers is counterproductive, since the repeated new growth process leads to the above-mentioned growth and crystallization problems, which ultimately also negatively impact the homogeneity of the HTSC layer. This also results in deterioration of the transfer of texture from the substrate layer to the HTSC layer.

As far as possible, the above-mentioned requirements should also be met by an HTSC layer arrangement in which the buffer layer and/or the HTSC layer may be manufactured by means of CSD. Owing to the associated processes that occur during thermal formation of the buffer and HTSC layers, special requirements must also be imposed on the production of these layers. In particular, the kinetics of layer formation and crystallization differ fundamentally from the demands on production of these layers by physical methods, such as pulsed laser deposition (PLD), thermal co-evaporation (TCE), metal-organic chemical vapor deposition (MOCVD), and the like.

### BRIEF SUMMARY OF THE INVENTION

The object of the invention is to provide a high-temperature superconductor layer arrangement that displays good growth properties on the substrate, may contain as few individual layers as possible, and permits growth of the HTSC layer that is as simple and flawless as possible.

This object is solved by the HTSC layer arrangement according to the invention, which comprises at least one substrate and a textured buffer layer. The buffer layer permits textured growth of a high-temperature superconductor. As described in more detail below, at least one layer of the buffer material comprises a rare-earth element cerium oxide. Surprisingly, including such a rare-earth element oxide provides a layer that has good diffusion barrier properties, displays good growth properties on the substrate, and also allows for good growth of, and a high degree of texture transfer to, the HTSC material on the layer, and which may be manufactured without undesirable foreign phases. Accordingly, it is possible to produce HTSC layer arrangements satisfying very high requirements that have just one buffer layer, which may moreover be manufactured by chemical solution deposition. Furthermore, a high quality buffer layer may be manufactured, even with relatively high layer thickness.

### DETAILED DESCRIPTION OF THE INVENTION

The rare-earth element and/or cerium in the rare earth element cerium oxide may be partially substituted. With respect to individual layers, substitution may be performed completely to form stoichiometric (ordered) modifications, or to form non-stoichiometric (homogeneous) mixed-crystal phases.

The rare-earth element cerium oxide may be a binary or multinary oxide that may also display further components and may be, for example, a main-group metal rare-earth element cerium oxide, a transition metal rare-earth element cerium oxide, or a mixed form thereof, such as a main-group metal transition metal rare-earth element cerium oxide. The rare-earth element cerium oxide preferably exclusively displays rare-earth elements as metals.

The rare-earth element cerium oxide may contain two or more different rare-earth elements (other than cerium), in which (rare-earth element/rare-earth element) cerium oxides, rare-earth element (cerium/rare-earth element) oxides or (rare-earth element/rare earth element) (cerium/rare-earth element) oxides may occur as homogeneous mixed-crystal phases. The rare-earth element and/or the cerium may thus be substituted by other rare-earth elements, independently of each other. In the above-mentioned compounds, the rare-earth element may be one or more metals selected from the group consisting of La, Nd, Sm, Eu, Gd, Y, and Yb, particularly La, Sm, Eu, and Gd. Particularly preferably, the rare-earth element is entirely La or La is contained as a rare-earth element.

The rare-earth elements and/or the cerium may be partially substituted by other transition metals, e.g., transition metals of the first, second and/or third subgroup, particularly by metals of the second and/or third subgroup, particularly one or more metals selected from the group consisting of Hf, Zr, Ta, and Nb, particularly Zr or Hf. Where appropriate, the rare-earth elements and/or transition metals of the above-mentioned oxides, possibly also the cerium, may also be partially substituted, independently of each other, by main-group metals, e.g., by one or more metals from the group consisting of alkali metals, alkaline-earth metals, metals of the third main group, or by metals or semimetals of the fourth or fifth main group, such as Rb, Cs, Sr, Ba, Ga, In, Tl, Sn, Pb, Bi, As, Sb, Se, and Te.

The rare-earth element cerium oxide may have the general formula RE₂₊ₓCe_{2+y}O_{z}, in which −2<x, y<2, preferably −1≦x, y≦1 or −0.5≦x, y≦0.5. It is preferably true that if x≦0, then y≧0, and if y≦0, then x≧0. Preferably, x=−y in each case. x and y may be 0, independently of each other. It may be that x+y=±∂, in which ∂ may be ≦0.5 to 1, preferably ≦0.2 to 0.3 or ≦0.15 to 0.1. If ∂ is less than 0, the cation lattice may display lattice vacancies; if ∂ is greater than 0, interstitial positions, such as octahedron gaps, may additionally be occupied. In particular, a may be equal to 0. RE represents one or more rare-earth elements selected from the group consisting of La, Y, Ce, Pr, Nd, Pm, Sm, Eu, Gd, Tb, Dy, Ho, Er, Tm, Yb, and Lu, preferably La or Ln (in which Ln represents Ce, Pr, Nd, Pm, Sm, Eu, Gd, Th, Dy, Ho, Er, Tm, Yb, or Lu) or only Ln. Preferably, Ln may in each case be one or more metals selected from the group consisting of Ce, Nd, Sm, Eu, Gd, and Yb. Further, z is selected to ensure neutral charge balance. If applicable, it may be 5≦z≦8 or 7≦z≦8, particularly z=7.

The buffer layer material may also be a rare-earth oxide of the general formula RE₂₋ₓCe_{2-y}O_{7±2z}, in which 0≦x, y, z, ≦1, RE is one or more rare-earth elements, and RE and/or Ce may be partially substituted.

RE and/or Ce may, independently of each other, be partially substituted by a metal M that represents one or more metals selected from the group consisting of transition metals (except rare-earth elements) and main-group metals, including Zn. M may in each case be one or more metals selected from the transition metals of the first, second and/or third subgroup, preferably of the second and/or third subgroup, with the exception of the lanthanides and actinides in each case. Preferably, M is one or more metals having a valence of 2 to 5 or of 3 to 5, particularly of 3 to 4 or of 4 to 5. If M represents several metals, they preferably have the same valence, preferably 3, 4, or 5. Thus, M may in each case be one or more metals selected from the group consisting of Sr, Ba, Ga, In, Ti, Sn, Pb, Bi, As, Sb, Se, Te, Ta, Nb, Hf, and Zr. In particular, M may be one or more metals from the group selected from hafnium, zirconium, tantalum, and niobium. In formula RE₂₊ₓCe_{2+y}MᵥO_{z}, it may be that −2≦x, y, v≦2, preferably −1≦x, y, v≦1 or −0.5≦x, y, v≦0.5. It is preferably the case in this context that x+y+v=±∂, in which ∂≦0.5 to 1, preferably ≦0.2 to 0.3 or ≦0.15 to 0.1 or 0. In particular, y may be equal to −v and x may be equal to 0, independently or simultaneously. In the case of formula RE₂₊ₓMᵥCe_{2+y}O_{z}, x may be equal to −v and y may be equal to 0, independently or simultaneously. RE may be selected as indicated above, and is particularly La and/or Y. Further, z is selected to ensure neutral charge balance. If applicable, it may be 5≦z≦8 or 7≦z≦8, particularly z=7.

The rare-earth element cerium oxide may also have the general formula Ln′₂₋ₓLn″ₓCe_{2-y}MᵥO_{z} in which 0≦x, y, v≦2, preferably 0≦x, y, v≦1, z may be between 5 and 8, preferably 6 to 8, Ln′ and Ln″ are each a rare-earth element, independently of each other, and M is defined as above. It may be that v=y. M may, in particular, be a tetravalent metal. In this context, Ln represents a lanthanide, such as Nd, Sm, Eu, Gd, Tb, Er, Yb or Lu, but not Ce. M may be selected as indicated above, e.g., a metal of the second or third subgroup, including combinations thereof. M may be Hf, Zr, Ta, and Nb, including combinations thereof. In particular, y may, however, also be equal to 0. Further, z is selected to ensure neutral charge balance. If applicable, it may be 5≦z≦8 or 7≦z≦8, particularly z=7.

The rare-earth element cerium oxide may also have the general formula (La,Ln)₂Ce₂O_{7±z} (particularly with Ln=Nd, Sm, Eu, Gd, Yb, including combinations thereof), in which La may be partially or completely substituted by Y.

The rare-earth element cerium oxide (including the above-mentioned modifications) may contain ≧about 5-10 atom % or ≧about 15 atom % Ce, preferably ≧about 20 to 30 atom % or ≧about 40 to 50 atom % cerium. The cerium content may be ≦about 95 atom % or ≦about 80 to 90 atom %, or ≦about 60 to 70 atom %, and also, where appropriate, ≦about 40 to 50 atom % or ≦about 30 atom %. In each case, these atom percentages are based on the total metal content of the oxide.

The content of rare-earth elements (RE) other than cerium, particularly also the La content, may be about 90 atom % to about 10 atom %, in which one, two, or more rare-earth elements may be present. The rare-earth element content (other than Ce), particularly also the La content, may be ≦95 about atom % or ≦about 80 to 90 atom %, or ≦about 60 to 70 atom %, and also, where appropriate, ≦about 40 to 50 atom % or ≦about 30 atom %. In each case, these atom percentages are based on the total metal content. The rare-earth element content (other than Ce), particularly also the La content, may generally be ≧about 5 to 10 atom % or ≧about 15 atom %, preferably ≧about 20 to 30 atom % or ≧about 40 to 50 atom %. If further rare-earth elements (other than cerium) are present in addition to lanthanum, the ratio of La:RE (other than Ce) may be, without limitation, about 1:10 to 10:1, particularly about 1:5 to 5:1 or about 1:4 to 4:1, preferably about 1:3 to 3:1 or about 1:2 to 2:1, particularly preferably about 2:3 to 3:2 or about 1:1. Preferably, the La content (in atom %) is in each case greater than that of other rare-earth elements (other than Ce).

The atomic ratio of Ce:rare-earth element (not Ce), particularly also the atomic ratio of Ce:La, may be about 1:10 to 10:1, particularly about 1:5 to 5:1 or about 1:4 to 4:1, preferably about 1:3 to 3:1 or about 1:2 to 2:1, particularly preferably about 2:3 to 3:2 or about 1:1.

In total, the rare-earth element content, including cerium, may be ≧about 20 to 30 atom %, ≧about 40 to 50 atom % or ≧about 60 to 70 atom %, or ≧about 80 to 90 atom %, and also, where appropriate, ≧about 95 to roughly about 100 atom %, based on the total metal content.

The buffer layer material may generally display a phase width in relation to the oxygen content. For example, z may vary between about 0 and 1 in the above-mentioned compounds; especially in relation to an ideal formula RE₂₊ₓCe_{2+y}O_{7±z}, also including the above-mentioned modifications, especially of formula (La,Ln)₂Ce₂O_{7±z}. Where appropriate, the oxygen lattice may also be sub-stoichiometric, i.e., z may be less than 0, but preferably not less than −1.

The rare-earth element cerium oxide may, for example, crystallize with an NaCl, fluorite, pyrochlore, perovskite or GdFeO₃ structure, possibly including ordered superstructures of the same. The buffer layer material preferably crystallizes with a fluorite structure, a pyrochlore structure or, where appropriate, another fluorite superstructure, as a result of which phase formation and/or crystallization take place faster during the annealing process, and layers with better properties may be obtained. It goes without saying that the content of an additional component may be selected in such a way that optimum adaptation of the lattice constants of the buffer layer material to those of the substrate and/or the HTSC material may be achieved, referring to the lattice constants in the layer plane of the layer arrangement, taking superstructures into consideration, where appropriate. For example, the lattice constants of the buffer layer material may lie at least roughly in the middle range of the lattice constants of the substrate and the HTSC layer, e.g., with a deviation of ≦about ±5 to 8% or ≦about 2 to 3% or ≦about 0.75 to 1%, in each case referring to the mean absolute value of the lattice constants of the substrate and the HTSC material in the principal plane of the layer arrangement. In the case of superstructures, the same explanation applies to the lattice constants of the buffer layer material transposed and scaled to the elementary cell of the substrate.

The textured buffer layer may contain at least one additional component that forms a homogeneous mixed-crystal phase and is a transition metal of the first subgroup and/or forms at least a partial melt with the preferably oxidic buffer material at an annealing temperature of ≦about 1,600° C. Because the additional component forms a homogeneous mixed-crystal phase with the buffer layer material, a buffer layer may be produced that displays very little, or virtually no, porosity, and additionally only very slight roughness, and may be manufactured with high tightness and virtually without cracks. Furthermore, a buffer layer of this kind may be manufactured by CSD. In particular, the rare-earth element cerium oxide layer may contain the additional component that forms a homogeneous mixed-crystal phase.

Due to this additional component, at least a partial melt may be formed during production of the buffer layer. That is, at least partial recrystallization of the buffer layer material may take place during the subsequent annealing treatment when an intermediate liquid phase is formed, at least in some areas. In this process, the texture of the substrate may be transferred to the buffer layer, and thus ultimately to the HTSC layer, far better than when using the buffer layer material without the additional component. Moreover, a buffer layer may be produced that has substantially reduced, or virtually no, porosity and microcracks, and that is furthermore substantially smoother than conventional layers. As a result, the HTSC layer grown on the buffer layer may likewise be very smooth and homogeneous, i.e., virtually free from pores or other areas that, like microcracks, impede superconductive continuity. Texture transfer may also be improved. Moreover, there is also a dramatic reduction in growth defects on the buffer layer, such as may occur in the area of pores of conventional buffer layers and may lead to HTSC areas with different crystal orientations. An HTSC layer of this kind displays enhanced physical and mechanical properties, particularly also with respect to superconductive properties, such as the critical current density and the absolute critical current I_{C}. As a result, it is also possible to manufacture electronic HTSC components with improved properties.

The substrate is preferably textured, particularly biaxially textured, i.e., perpendicular to the layer plane on which the HTSC material is grown, and in a direction within the layer plane, e.g., in the longitudinal direction of the strip in the case of a strip-shaped substrate. The substrate may be strip-shaped but may also have different dimensions, e.g., in the form of more isometric layers. The buffer layer usually consists of an oxide-ceramic material or a metal oxide.

Preferably, the additional component forms only a partial melt with the buffer layer material at temperatures of about 1,600 to 500° C., about 1,400 to 600° C., about 1,250 to 700° C., or about 1,100 to 800° C., such that the solid and liquid phases of the buffer layer material coexist with each other, or a virtually homogeneous or complete melt.

In particular, the additional component and its concentration in the buffer layer material, may be selected in such a way that it forms at least a partial melt when subjected to annealing treatment at ≦about 1,300 to 1,400° C., preferably ≦about 1,100 to 1,200° C. or ≦about 900 to 1,000° C. It goes without saying that the annealing temperature must be selected in such a way that the buffer layer material does not suffer any unwanted decomposition or volatilization of components and the substrate is not impaired, e.g., by formation of undesirable phases or detrimental alteration of its texture.

The additional component may be used in the buffer layer material at such a concentration that preferably no amorphous phases and no mixed phases are formed during annealing treatment at ≦about 1,500 to 1,600° C., but also during further cooling down to, for example, ≦about 800 to 900° C., ≦about 600 to 700° C., <about 400 to 500° C., about 200 to 300° C. or down to room temperature, or lower temperatures down to approx. 70 to 80° Kelvin or lower, e.g., due to phase transitions The homogeneous solid mixed-crystal phase also preferably displays long-term stability below the annealing temperature. The homogeneous mixed-crystal phase containing the additional component may display long-term kinetic stability at room temperature and/or at the operating temperature of the HTSC material, and it is preferably also thermodynamically stable in the temperature range from annealing treatment (see above) to the operating temperature of the HTSC material, such that separation processes or phase segregation, precipitation of amorphous phases, or other phase changes do not occur.

Preferably, the additional component forming the homogeneous mixed-crystal phase is one or more metals of the first subgroup, e.g., Cu, Ag, Ti, V, Cr, Mn or Zn, particularly preferably Cu and/or Ag, or contains such a metal. Where appropriate, Fe, Ni and/or Co may also be used, although they are not preferred due to the magnetic properties of their compounds. Particularly preferred are copper and/or silver. The above-mentioned transition metals may in each case be used singly or in combination, e.g., copper in combination with one or more of the other metals mentioned above. Where appropriate, the additional component may, alternatively or additionally, also contain other metals, e.g., one or more metals selected from the group consisting of main-group metals, such as alkali and/or alkaline-earth metals, metals and semimetals of the third, fourth, fifth or sixth main group, insofar as they form a homogeneous mixed-crystal phase with the buffer layer material that forms at least a partial melt during annealing treatment at ≦about 1,600° C. or the above-mentioned temperatures, and is not subject to any phase transitions or precipitation of other phases, including the formation of amorphous phases, at lower temperatures, particularly at the temperatures mentioned above. The additional component is preferably present in the form of an oxide and forms a mixed oxide with the buffer layer material, and the additional component may be introduced by means of a precursor. The additional component is preferably predominantly or entirely present in a medium or low oxidation state >0, e.g., in an oxidation state of 1, 2, 3 or 4, preferably 1 to 3, or an oxidation state of 1 or 2, insofar as this oxidation state is sufficiently stable. In particular, copper may be present in the form of Cu (I).

Moreover, the additional component should generally not have a significant tendency, or any tendency, to diffuse into the HTSC layer and cause (detrimental) changes in the mechanical and/or physical properties thereof, particularly reduction of the critical current density and/or the absolute critical current.

The additional component, or the combination of additional components, may be present at a concentration of up to about 40 atom % based on the total metal content of the buffer layer, or also at a higher concentration, where appropriate, insofar as a homogeneous mixed-crystal phase is formed with the buffer layer material that is preferably also stable below the annealing temperature, as indicated above. The additional component may be present at a concentration of ≧about 1 to 2 atom % or ≧about 3 to 5 atom %, preferably at a concentration of ≧about 7 to 10 atom %, based on the total metal content of the buffer layer material in each case. The concentration of the additional component, or of the combination of additional components, may be ≦about 40 atom % or ≦about 30 to 35 atom %, or also ≦about 20 to 25 atom %, where appropriate, based on the total metal content of the buffer layer.

The buffer layer may consist of multiple individual layers, the compositions of each of which may differ, e.g., with respect to the buffer layer material, the cerium content, the content or species of the further doping elements and/or the additional component forming a mixed phase. The individual buffer layers may, however, also at least essentially display the same composition, e.g., to produce a buffer layer of greater thickness.

The mixed-crystal phase buffer layer containing the additional component may be applied directly to the substrate. Where appropriate, a nucleation layer, which may consist of an oxidic material, such as a titanate or zirconate, e.g., calcium titanate, may also be applied to the substrate. This nucleation layer does not serve as a buffer layer, but essentially prepares the substrate surface. It generally consists of a plurality of isolated, insular structures and does not constitute an adequate diffusion barrier.

Alternatively or additionally, the additional component in the buffer layer consisting of several layers, which forms a mixed-crystal phase with the buffer layer material, may form the layer adjacent to the HTSC layer. The other layers of the buffer layer may be conventional buffer layers not displaying an additional component forming a mixed-crystal phase. Where appropriate, several buffer material layers according to the invention may also be provided, each with one or more component(s) forming a mixed phase, in which different components, or components in different concentrations, are present in the individual layers. To form the buffer material layer comprising several layers, the buffer materials may, for example, be applied to the respective substrates in the form of solvent-based solutions, and the solvent partially or completely removed. This may be followed by thermal treatment, where appropriate. After this, a further buffer material layer of the same or a different composition may then be applied. Preferably, the annealing treatment is performed, producing the oxide-ceramic buffer material, after formation of all the buffer material layers; where appropriate, further buffer material layers may also be applied after the annealing treatment. The solvent may be partially or completely removed and the buffer material applied in the form of a partially or completely decomposed precursor during the thermal treatment performed after application of the buffer material layer.

The buffer layer according to the invention may be formed in just one layer, e.g., by a single application of the solution of buffer layer material in the case of CSD, meaning that the HTSC layer may already be applied following thermal pretreatment and annealing. Where appropriate, however, the buffer layer according to the invention may also be applied to a further buffer layer, e.g., a layer of a simple, binary, or multinary oxide, particularly a rare-earth oxide, e.g., on a cerium oxide layer (CeO₂, in which the oxygen may also be sub-stoichiometric), a rare-earth(RE)/rare earth(RE) oxide layer or a rare earth(RE)/transition metal(TM) layer (e.g., a lanthanum zirconate layer, rare-earth zirconate layer, or transition metal cerium oxide layer), which may display the composition La₂Zr₂O₇₊ₓ, RE₂Zr₂O₇₊ₓ or TM₂Ce₂O₇₊ₓ with 0≦x≦1. These substrate layers may contain the additional component forming a homogeneous mixed phase, such as copper. Incidentally, these layers may also be substituted, as described above with regard to the buffer layers according to the invention. In particular, the individual buffer layers may in each case consist of the same material.

The buffer layer material may be applied in the form of a metal-organic precursor, such as a β-diketonate, particularly an acetylacetonate, acetate, alkyl carboxylate or the like. In general, a suitable solvent may be used that may contain, or consist of, without limitation a ketone, e.g., acetone, one or more alcohols, or one or more carboxylic acids. In particular, C₂-C₈, C₃-C₆, or C₃-C₄ carboxylic acids may be used, each of which may have straight or branched chains, particularly also propionic acid and/or pivalic acid. Where appropriate, the above-mentioned solvents may also be used in combination with each other. The organic solvent may be essentially anhydrous.

Particularly preferably, the buffer layer material is used in the form of an alkyl carbonate containing about 1 to 10, preferably about 2 to 8, more preferably about 3 to 6 C atoms, e.g., in the form of a propionate or pivalonate. The alkyl carbonate may generally have straight or branched chains or, where appropriate, also be cyclic.

The buffer layer material may also be applied in an aqueous solution. Suitable for use as water-soluble salts are, in particular, nitrates, carboxylates, particularly acetates, citrates or tartrates, individually or in combination. The aqueous solution may be set to a pH value of about 4 to 8, preferably about 5 to 7 or more preferably about 6 to 7. The solution is preferably buffered, particularly by a thermally decomposable or volatilizable buffer, particularly ammonia or an ammonium salt.

The annealing treatment for crystallizing the buffer material may at least partly take place in a reducing atmosphere, e.g., under forming gas or another suitable gas with at least similar reductive capacity. The forming gas (N₂/H₂) may contain about 0.1 to 15% or up to about 20%, about 0.2 to 10%, about 0.5 to 5% or about 1 to 5%, e.g., approx. 3% H₂ (percent by volume in each case). The buffer layer that contains the rare-earth element cerium oxide and is applied directly to the substrate may also be manufactured by an annealing treatment in a non-reducing atmosphere, e.g., under pure nitrogen or another inert gas. Depending on the circumstances, this may also apply to other or all buffer layers of a multilayer buffer material coating. If the buffer layer containing the rare-earth element cerium oxide is applied to an intermediate layer of buffer material, located between it and the substrate, the buffer layer may be manufactured by an annealing treatment in a reducing atmosphere, e.g., under forming gas; depending on the circumstances, this may also apply to the manufacture of other or all buffer layers according to the invention. In general, individual buffer layers may be manufactured under a non-reducing atmosphere, and other buffer layers of the same buffer layer structure of an HTSC layer arrangement may be manufactured under a reducing atmosphere.

The buffer layer manufactured according to the invention may display a critical current density of ≧about 0.5 MA/cm², e.g., about 0.5 to 2.5 MA/cm², about 0.5 to 1.5, or up to about 2 MA/cm². The critical current density may thus be ≧about 0.75 MA/cm² or ≧about 1 MA/cm².

The annealing treatment may be performed in such a way that the buffer layer containing the additional component has a porosity of ≦about 25 to 30%, ≦about 15 to 20%, ≦about 5 to 10%, or that the layer is at least essentially free from pores.

The annealing treatment may be performed in such a way that the buffer layer containing the additional component displays an RMS roughness (root-mean-square roughness) of ≦about 2.5 to 2 nm, preferably ≦about 1.6 to 1.8 nm or ≦about 1.2 to 1.4 nm, particularly preferably ≦about 1.0 to 0.8 nm, determined on an area of 1×1 μm².

The high-temperature superconductor applied to the buffer layer may be a rare-earth element copper oxide, particularly a rare-earth element alkaline-earth metal oxide, where, independently of each other, the rare-earth element may be yttrium and the alkaline-earth metal may be barium. It goes without saying that particularly the rare-earth element, e.g., yttrium, and/or the alkaline-earth metal, e.g., barium, may be partially substituted by other metals, e.g., by other rare-earth elements or alkaline-earth metals. In particular, the HTSC material may be a Y—Ba—Cu oxide (YBa₂Cu₃Oₓ) or a Bi—Sr—Ca—Cu oxide. For the purposes of the invention, the term “high-temperature superconductor” is generally to be taken to mean a superconductor with a superconductive transition temperature of ≧about 77° Kelvin, although another ceramic (oxidic) superconductor may generally also be applied to the buffer layer, where appropriate.

The buffer layer may generally display a thickness of, without limitation, about 0.02 to 2 μm, or generally ≦about 5 μm, and, where appropriate, about 0.1 to 1 μm, about 0.1 to 0.5 μm or about 0.1 to 0.3 μm. The thickness of the substrate is not limited, as long as it displays sufficient mechanical strength. It may be about 5 to 1,000 μm, about 10 to 500 μm, about 25 to 250 μm or about 50 to 100 μm. A material promoting growth of the buffer layer may be applied to the substrate, preferably with an insular structure. Without being limited, the HTSC layer may display a thickness of ≧about 0.05 μm, particularly about 0.1 to 50 μm or about 0.25 to 10 μm, preferably about 0.5 to 5 μm.

The substrate may be a suitable metal or an alloy, e.g., nickel or a nickel alloy, such as tungsten-doped nickel (e.g., Ni containing 5 to 10 atom % W), Hastelloy or the like. Where appropriate, however, the substrate may also be a ceramic material.

An example of the invention is described below and explained on the basis of the practical examples.

All coatings were applied by dip coating on a continuous strip-coating system with integrated drying section. However, other liquid-coating methods may also be used, e.g., printing methods, such as inkjet or screen printing, spray-coating methods, coating via capillaries or slot nozzles, or also batch-type coating methods. In all examples, the drawing speed was 10 m/h for a strip with a width of 1 cm. The substrate strip used in all instances was a biaxially roll-textured Ni strip with 5 atom % W having a thickness of 80 μm. 10 ml of each coating solution were prepared. The results from all of the Examples are compiled in the Table.

### Example 1

### Lanthanum Cerate

A 0.4 molar solution (referred to as La) was prepared from La acetate and Ce acetate at an atomic ratio of 1:1 in propionic acid. The solution was evaporated by one-half in a rotary evaporator and diluted to original volume with propionic acid.

A metal strip (Ni with 5 atom % W) was directly continuously dip-coated with the solution at 10 m/h and, after drying, the layer was crystallized within 1 h at 1,000° C. under forming gas (5% H₂ in N₂).

### Example 1a

### Lanthanum Cerate Double Coating

Using the same method, part of the coating from Example 1 was coated, dried and crystallized a second time, but heat treatment was performed under 100% nitrogen.

### Example 2

### Lanthanum Cerate

Cerium nitrate and lanthanum nitrate (metal ratio 1:1) were dissolved in citric acid at a ratio of 1:3 (total metal ions: citric acid). Ammonia and water were added to produce a 0.2 molar solution with a pH value of 6.

In accordance with the general description of the experiment set forth above, the solution was applied to a substrate strip, to which a double lanthanum zirconate layer had previously been applied. Drying took place within 30 minutes at 200° C. in air; the annealing treatment was performed within 30 minutes at 900° C. under forming gas (5% H₂ in N₂).

### Example 2a

### Lanthanum Cerate Double Coating

Using exactly the same method, part of the coating from Example 2 was coated, dried and crystallized under forming gas a second time.

### Example 3

### Lanthanum Cerate

Lanthanum propionate, cerium propionate and copper propionate were dissolved at a molar ratio of 9:9:1 in propionic acid in such a way as to obtain a 0.4 molar solution with respect to lanthanum.

The solution was applied directly to a metal substrate strip in accordance with the general description of the experiment set forth above. Drying took place within 10 minutes at 120° C. in air; the annealing treatment was performed within 20 minutes at 950° C. under forming gas (5% H₂ in N₂).

### Example 4

### Lanthanum Zirconate (Reference Example)

Lanthanum propionate, zirconium propionate and copper propionate were dissolved at a molar ratio of 9:9:1 in propionic acid in such a way as to obtain a 0.4 molar solution with respect to lanthanum.

The solution was applied directly to a metal substrate strip in accordance with the general description of the experiment set forth above. Drying took place within 10 minutes at 120° C. in air; the annealing treatment was performed within 20 minutes at 1,000° C. under forming gas (5% H₂ in N₂).

### Example 4a

### Lanthanum Zirconate Double Coating (Reference Example)

Using exactly the same method, part of the coating from Example 4 was coated, dried and crystallized a second time.

All buffer layers were subsequently coated with a standard HTSC layer. A solution of yttrium, barium and copper trifluoroacetate (metal ratio 1:2:3) in anhydrous methanol was prepared for this purpose. Coating was performed on a continuous coating system at a drawing speed of 8 m/h. Drying took place within 30 minutes in air, and was followed by pyrolysis within 2 h at temperatures of 190 to 400° C. (air, dew point 20° C.). Reaction and crystallization took place within 1 h between 400 and 790° C., and within 1 h at 790° C. (100 ppm oxygen in nitrogen, dew point 20° C.). Oxygen loading (450° C., 1 h, 100% oxygen) was followed by cooling and measurement of the critical superconductivity parameters on an inductive measuring system (Cryosmay, Messrs. THEVA). The critical current density was determined at a superconductive layer thickness of 280 nm.

Table of Results

| Experiment No. | Critical current density [MA/cm²] |
|---|---|
| 1 | 0.2 |
| 1a | 1.5 |
| 2 | 0.1 |
| 2a | 1.1 |
| 3 | 0.5 |
| 4 | 0 |
| 4a | 0 |

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A layer arrangement for producing a high-temperature superconductor layer arrangement, wherein the layer arrangement comprises at least one substrate and a textured buffer layer, the textured buffer layer comprises an oxidic material that enables textured growth of a high-temperature superconductor, the textured buffer layer comprises at least one layer of buffer material comprising a rare-earth element cerium oxide comprising lanthanum, and the rare-earth element cerium oxide has a cerium content of about 5 atom % to about 95 atom % Ce and a content of rare-earth elements other than cerium of about 95 atom % to about 5 atom %.

2. The layer arrangement according to claim 1, wherein the rare-earth element cerium oxide further comprises at last one rare-earth metal element selected from the group consisting of Nd, Sm, Eu, Gd, Y, and Yb.

3. The layer arrangement according to claim 1, wherein the at least one layer of buffer material comprises a rare-earth element cerium oxide having a general formula RE₂₊ₓCe_{2+y}O_{z}, wherein −2<x, y<2, RE represents one or more rare-earth elements, and z is selected to achieve neutral charge balance.

4. The layer arrangement according to claim 1, wherein at least one of the rare-earth element and the cerium in the rare-earth element cerium oxide is partially substituted by one or more metals selected from the group consisting of Hf, Ta, Zr, Pb, and Nb.

5. The layer arrangement according to claim 1, wherein the rare-earth element cerium oxide contains at least about 25 atom % Ce, at least about 25 atom % La, or a combination thereof, based on a total metal content of the oxide.

6. The layer arrangement according to claim 1, wherein the rare-earth element cerium oxide crystallizes with a fluorite structure.

7. The layer arrangement according to claim 1, wherein the at least one layer of buffer material comprises at least one additional component that forms a homogeneous mixed-crystal phase and is a transition metal of the first subgroup or forms at least a partial melt with the oxidic buffer material at an annealing temperature of about 1,250 to 1,600° C.

8. The layer arrangement according to claim 7, wherein the transition metal is selected from the group consisting of copper, silver, and a combination thereof.

9. The layer arrangement according to claim 7, wherein the additional component is present in a concentration of up to about 40 atom %, based on a total metal content of the buffer layer.

10. The layer arrangement according to claim 1, further comprising a high-temperature superconductor layer.

11. The layer arrangement according to claim 10, wherein the textured buffer layer comprises at least two layers and is located between the at least one substrate and the high-temperature superconductor layer, and wherein each of the at least two layers independently comprises a rare-earth element cerium oxide.

12. The layer arrangement according to claim 1, wherein the textured buffer layer comprises only layers comprising an additional component that forms a homogeneous mixed-crystal phase.

13. The layer arrangement according to claim 1, wherein the textured buffer layer has a single-layer design.

14. A method for manufacturing a layer arrangement according to claim 1, comprising applying to the at least one substrate the textured buffer layer that enables textured growth of the high-temperature superconductor.

15. The method according to claim 14, wherein at least one of the rare-earth element and the cerium in the rare-earth element cerium oxide is partially substituted.

16. The method according to claim 14, wherein the at least one layer of buffer material comprises a rare-earth element cerium oxide having general formula RE₂₋ₓCe_{2-y}O_{7±2z} wherein 0≦x, y, z≦1, RE represents one or more rare-earth elements, z is selected to achieve neutral charge balance, and at least one of RE and Ce may be partially substituted.

17. The method according to claim 14, comprising applying the textured buffer layer directly to the substrate.

18. The method according to claim 14, further comprising manufacturing the textured buffer layer by chemical solution deposition.

19. The method according to claim 14, wherein applying the textured buffer layer to the substrate comprises manufacturing the textured buffer layer by an annealing treatment in a non-reducing atmosphere.

20. The method according to claim 14, further comprising applying an intermediate layer of buffer material to the substrate and applying the textured buffer layer to the intermediate layer by an annealing treatment in a reducing atmosphere.

21. The method according to claim 14, further comprising applying a high-temperature superconductor layer to the textured buffer layer on the at least one substrate, wherein the textured buffer layer only comprises layers that comprise a rare-earth element cerium oxide.

22. The method according to claim 14, wherein the textured buffer layer exhibits a critical current density of at least about 0.5 MA/cm².

23. The method according to claim 14, wherein the textured buffer layer comprises at least one additional component that forms a homogeneous mixed-crystal phase and is a transition metal of the first subgroup or forms at least a partial melt with the oxidic buffer material at an annealing temperature of about 1,250 to 1,600° C.

24. The method according to claim 14, wherein the textured buffer layer has a porosity of ≦about 25% and/or an RMS roughness of ≦about 1.8 nm.
